(19) United States
(12) Patent Application Publication
(10) Pub. No.: US 2026/0038583 A1
(43) Pub. Date: Feb. 5, 2026

(54) CHIP RANK IDENTIFICATION CIRCUIT

(71) Applicant: NANYA TECHNOLOGY CORPORATION, New Taipei City (TW)

(72) Inventors: Chan Li Lin, New Taipei City (TW); Chih Hsiang Chang, New Taipei City (TW)

(73) Assignee: NANYA TECHNOLOGY CORPORATION, New Taipei City (TW)

(21) Appl. No.: 18/793,958

(22) Filed: Aug. 5, 2024

(51) Int. Cl. G11C 11/4096; G11C 11/4099; H01L 23/48; H01L 25/065

(52) U.S. Cl. CPC G11C 11/4096; G11C 11/4099; H01L 23/481; H01L 25/0657; H01L 2225/06544

(57) ABSTRACT

A chip rank identification circuit is provided. A first control circuit couples a resistor circuit to a first operating voltage or a first contact based on whether a chip is connected to a ost-stage chip. A second control circuit couples the resistor circuit to a second operating voltage or a third contact based on whether the chip is connected to a pre-stage chip. An identification circuit determines a rank of the chip based on a reference voltage provided by the resistor circuit.

### BACKGROUND OF THE INVENTION

### Field of the Invention

The invention relates to a detection circuit, and in particular to a chip rank identification circuit.

### Description of Related Art

The current dynamic random-access memory integrated circuit (DRAM IC) has a limited

area, and a plurality of DRAM ICs need to be connected and stacked via through silicon vias (TSVs) to achieve the object of increasing capacity. However, each stacked IC needs to obtain the rank position thereof in order to correctly access the stacked DRAM rank.

### SUMMARY OF THE INVENTION

The invention provides a chip rank identification circuit that may effectively use TSV area and achieve chip rank identification.

A chip rank identification circuit of the invention is suitable for detecting a rank of a chip. The chip rank identification circuit has a first contact and a second contact, and includes a detection circuit and an identification circuit. The detection circuit includes a first switching circuit, a resistor circuit, and a first control circuit. The first switching circuit is coupled to the first contact. The resistor circuit is coupled to the first switching circuit. The first control circuit is coupled to the first switching circuit and the second contact and determines whether the chip is coupled to a post-stage chip based on a voltage on the second contact to control the first switching circuit to switch the resistor circuit to be coupled to the first contact or switch the resistor circuit to be coupled to a first operating voltage. The identification circuit is coupled to the resistor circuit and determines the rank of the chip based on a reference voltage provided by the resistor circuit.

In an embodiment of the invention, the detection circuit includes a third contact, a fourth contact, a second switching circuit; and a second control circuit. The second control circuit is coupled to the second switching circuit and the fourth contact and determines whether the chip is coupled to a pre-stage chip based on a voltage on the fourth contact to control the second switching circuit to switch the resistor circuit to be coupled to the third contact or switch the resistor circuit to be coupled to a second operating voltage.

In an embodiment of the invention, the identification circuit includes a voltage dividing circuit, a selection circuit, and a determination circuit. The voltage dividing circuit is coupled to the resistor circuit and divides the reference voltage to generate a first divided voltage. The selection circuit selects the reference voltage or the first divided voltage as an output signal according to the reference voltage, the first divided voltage, a first threshold voltage, and a second threshold voltage. The determination circuit determines the rank of the chip based on the output signal.

In an embodiment of the invention, the selection circuit includes a first comparator circuit and a second comparator circuit. Positive and negative input terminals of the first comparator circuit are coupled to the first threshold voltage and the reference voltage. Positive and negative input terminals of the second comparator circuit are coupled to the second threshold voltage and the first divided voltage. The multiplexer circuit is coupled to output terminals of the first comparator circuit and the second comparator circuit and outputs the reference voltage or the first divided voltage according to a comparison result of the first comparator circuit and the second comparator circuit, and the determination circuit determines the rank of the chip according to the output signal.

In an embodiment of the invention, the determination circuit includes a plurality of comparators, a plurality of resistors, and a logic circuit. Positive input terminals of the plurality of comparators receive the output signal. The plurality of resistors are connected in series between the first threshold voltage and a ground, and nodes between adjacent resistors are coupled to negative input terminals of corresponding comparators. The logic circuit is coupled to output terminals of the plurality of comparators and the fourth contact, and outputs an identification signal indicating the rank of the chip based on output voltages of the comparators and the voltage on the fourth contact.

In an embodiment of the invention, the resistor circuit includes a first resistor and a second resistor. The second resistor is connected in series with the first resistor between the first switching circuit and the second switching circuit, and a common contact of the first resistor and the second resistor generates the reference voltage.

In an embodiment of the invention, the first switching circuit is a multiplexer circuit, an input terminal of the multiplexer circuit is coupled to the first operating voltage and the first contact, an output terminal of the multiplexer circuit is coupled to the resistor circuit, and a control terminal of the multiplexer circuit is coupled to the first control circuit.

In an embodiment of the invention, the first control circuit includes a transistor, a first terminal thereof is coupled to the control terminal of the multiplexer circuit and the second contact, a second terminal of the transistor is coupled to a ground, a control terminal of the transistor is controlled by an enabling signal to be turned on, and the transistor generates a selection control signal based on the voltage on the first terminal of the transistor to control the multiplexer circuit to couple the resistor circuit to the first contact or the first operating voltage.

In an embodiment of the invention, the second switching circuit is a multiplexer circuit, an input terminal thereof is coupled to the second operating voltage and the third contact, an output terminal of the multiplexer circuit is coupled to the resistor circuit, and a control terminal of the multiplexer circuit is coupled to the second control circuit.

In an embodiment of the invention, the second control circuit includes a transistor, a first terminal thereof is coupled to the control terminal of the multiplexer circuit and the fourth contact, a second terminal of the transistor is coupled to a ground, a control terminal of the transistor is controlled by an enabling signal to be turned on, and the transistor generates a selection control signal based on the voltage on the first terminal of the transistor to control the multiplexer circuit to connect the resistor circuit to the third contact or the second operating voltage.

In an embodiment of the invention, the third contact is directly or indirectly connected to a first pre-stage connection TSV.

In an embodiment of the invention, the chip is coupled to a pre-stage chip by the first pre-stage connection TSV.

In an embodiment of the invention, the fourth contact is directly or indirectly connected to a second pre-stage connection TSV, and the chip is coupled to the pre-stage chip by the second pre-stage connection TSV.

In an embodiment of the invention, the first contact is directly or indirectly connected to a first post-stage connection TSV.

In an embodiment of the invention, the chip is coupled to a poste-stage chip by the first post-stage connection TSV.

In an embodiment of the invention, the second contact is directly or indirectly connected to a second post-stage connection TSV, and the chip is coupled to the post-stage chip by the second post-stage connection TSV.

Based on the above, the first control circuit of an embodiment of the invention couples the resistor circuit to the first operating voltage or the first post-stage connection TSV based on the connection situation with the post-stage chip. The second control circuit couples the resistor circuit to the second operating voltage or the first pre-stage connection TSV based on the connection situation with the pre-stage chip. The identification circuit may determine the rank of the chip based on the reference voltage provided by the resistor circuit. Since in an embodiment of the invention, only two TSVs are occupied between two chips, the area of TSVs may be effectively used and rank identification of the chips may be achieved.

In order to make the aforementioned features and advantages of the disclosure more comprehensible, embodiments accompanied with figures are described in detail below.

### BRIEF DESCRIPTION OF THE DRAWINGS

FIG. 1 and FIG. 2 are schematic diagrams of a chip rank identification circuit according to an embodiment of the invention.

FIG. 3 is a schematic diagram of resistor circuits of a plurality of chips coupled in series

according to an embodiment of the invention.

FIG. 4 is a diagram of the relationship between chip rank and resistor size according to an embodiment of the invention.

FIG. 5 is a schematic diagram of an identification circuit according to an embodiment of the invention.

### DESCRIPTION OF THE EMBODIMENTS

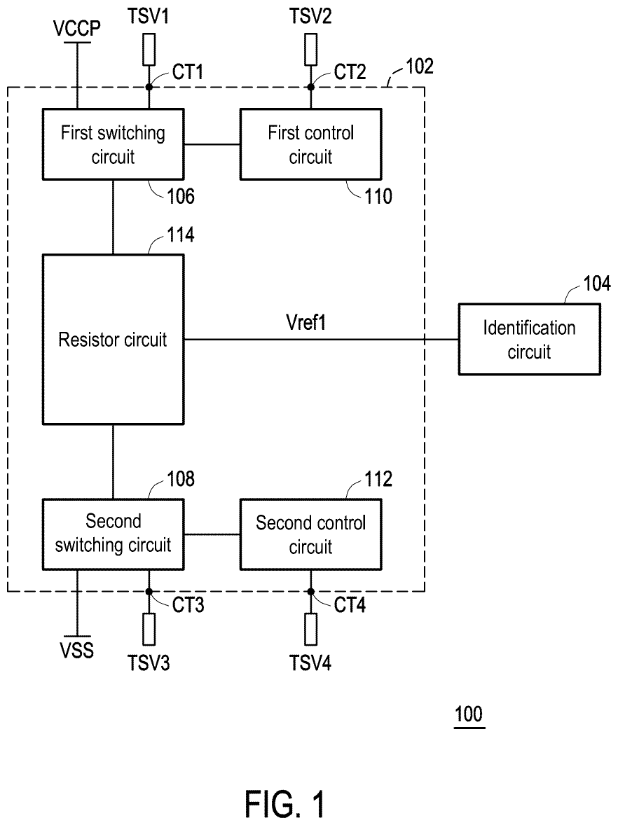

FIG. 1 is a schematic diagram of a chip rank identification circuit according to an embodiment of the invention. Please refer to FIG. 1. A chip rank identification circuit 100 may be disposed in each chip in a chip stack, so that each chip may automatically determine the chip rank thereof. The chip rank identification circuit 100 may include a detection circuit 102 and an identification circuit 104, wherein the detection circuit 102 may have contacts CT1˜CT4 and include a first switching circuit 106, a second switching circuit 108, a first control circuit 110, a second control circuit 112, and a resistor circuit 114. Since there may be process structures between the contacts and the TSVs to enhance the functionality or to strengthen the structure, the contacts CT1, CT2, CT3 and CT4 are directly or indirectly connected to the first post-stage connection TSV1, a second post-stage connection TSV2, a first pre-stage connection TSV3, and a second pre-stage connection TSV4 respectively. The resistor circuit 114, the first switching circuit 106, and the second switching circuit 108 are coupled in series between the contacts CTI and CT 3, the resistor circuit 114 is also coupled to the identification circuit 104, the control circuit 110 is coupled to the first switching circuit 106 and the contact CT 2, and the control circuit 112 is coupled to the second switching circuit 108 and the contact CT4.

The first control circuit 110 may determine whether the chip is coupled to the post-stage chip based on the voltage on the second post-stage connection TSV2 (that is, determine whether a chip is stacked above the chip adopting the chip rank identification circuit 100) to control the first switching circuit 106 to switch the resistor circuit 114 to be coupled to the first post-stage connection TSV1 so as to be coupled to the resistor circuit of the post-stage chip or switch the resistor circuit 114 to be coupled to a first operating voltage VCCP. For example, when the voltage on the second post-stage connection TSV2 is the first preset voltage, the first control circuit 110 may determine that the second post-stage connection TSV2 is coupled to the post-stage chip and control the first switching circuit 106 to switch the resistor circuit 114 to be coupled to the first post-stage connection TSV1 so as to be coupled to the resistor circuit of the post-stage chip. In contrast, if the voltage on the second post-stage connection TSV2 is not the first preset voltage, it may be determined that the chip adopting the chip rank identification circuit 100 is the top chip. At this time, the first control circuit 110 controls the first switching circuit 106 to switch the resistor circuit 114 to be coupled to the first operating voltage VCCP.

Similarly, the second control circuit 112 may determine whether the chip is coupled to the pre-stage chip based on the voltage on the second pre-stage connection TSV4 (that is, determine whether the chip adopting the chip rank identification circuit 100 is stacked above the pre-stage chip) to control the second switching circuit 108 to switch the resistor circuit 114 to be coupled to the first pre-stage connection TSV3 so as to be coupled to the resistor circuit of the pre-stage chip or switch the resistor circuit 114 to be coupled to a second operating voltage VSS, wherein the second operating voltage VSS may be, for example, the ground voltage, but is not limited thereto. For example, when the voltage on the second pre-stage connection TSV4 is the second preset voltage, the second control circuit 112 may determine that the second pre-stage connection TSV4 is coupled to the pre-stage chip and control the second switching circuit 108 to switch the resistor circuit 114 to be coupled to the first pre-stage connection TSV3 so as to be coupled to the resistor circuit of the pre-stage chip. In contrast, if the voltage on the second pre-stage connection TSV4 is not the second preset voltage, it may be determined that the chip adopting the chip rank identification circuit 100 is the bottom chip. At this time, the second control circuit 112 controls the second switching circuit 108 to switch the resistor circuit 114 to be coupled to the second operating voltage VSS.

The resistor circuit 114 may generate a reference voltage Vref1 to the identification circuit 104 corresponding to the stacking situation of the chip adopting the chip rank identification circuit 100 with other chips, and the identification circuit 104 may determine the rank of the chip adopting the chip rank identification circuit 100 based on the reference voltage Vref1.

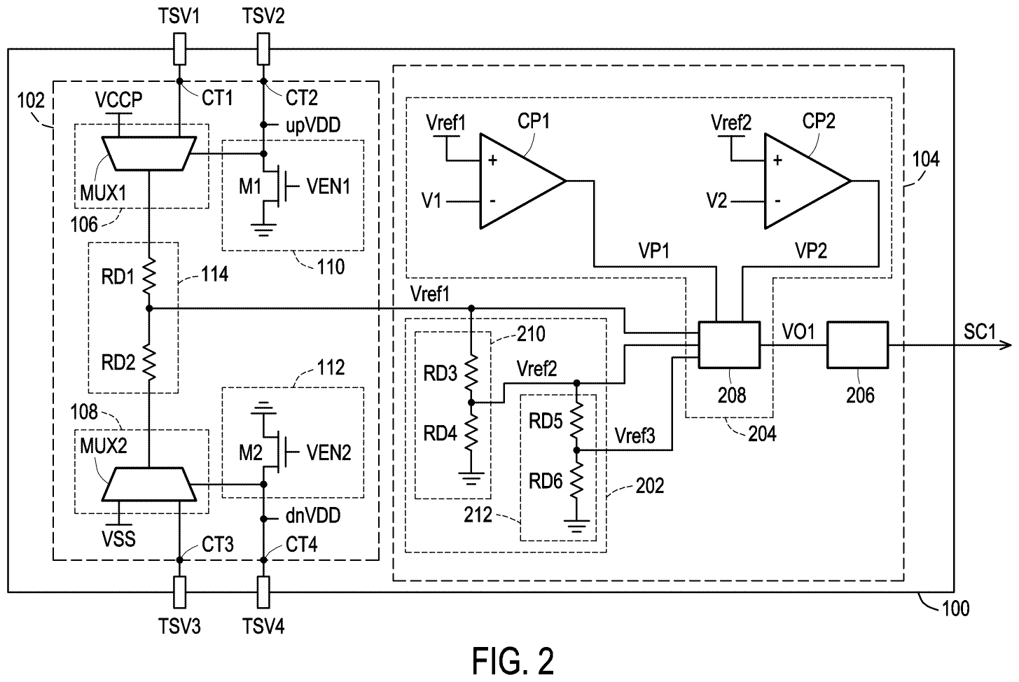

In detail, the implementation of the chip rank identification circuit 100 is shown in FIG. 2. The first switching circuit 106 and the second switching circuit 108 may be implemented as a multiplexer circuit MUX1 and a multiplexer circuit MUX2 respectively, and the first control circuit 110 and the second control circuit 112 may be implemented as a transistor M1 and a transistor M2 respectively. The resistor circuit 114 may include, for example, resistors RD1 and RD2. The resistors RD1 and RD2 may have the same resistance value, but are not limited thereto.

The input terminal of the multiplexer circuit MUX1 is coupled to the first operating voltage VCCP and the first post-stage connection TSV1, one terminal of the transistor M1 is coupled to the second post-stage connection TSV2 and the control terminal of the multiplexer circuit MUX1, another terminal of the transistor M1 is coupled to the ground, the control terminal of the transistor M1 is controlled by an enabling signal VEN1 to be turned on, and the transistor M1 may generate a selection control signal for controlling the multiplexer circuit MUX1 on one terminal coupled to the second post-stage connection TSV2 to control the multiplexer circuit MUX1 to connect the resistor circuit 114 to the first post-stage connection TSV1 or the first operating voltage VCCP. The resistors RD1 and RD2 are coupled in series between the output terminal of the multiplexer circuit MUX1 and the output terminal of the multiplexer circuit MUX2. The common contact of the resistors RD1 and RD2 is coupled to the identification circuit 104. The input terminal of the multiplexer circuit MUX2 is coupled to the second operating voltage VSS and the first pre-stage connection TSV3, one terminal of the transistor M2 is coupled to the second pre-stage connection TSV4 and the control terminal of the multiplexer circuit MUX2, another terminal of the transistor M1 is coupled to the ground, the control terminal of the transistor M2 is controlled by an enabling signal VEN2 to be turned on, and the transistor M2 may generate a selection control signal for controlling the multiplexer circuit MUX2 on one terminal coupled to the second pre-stage connection TSV4 to control the multiplexer circuit MUX2 to connect the resistor circuit 114 to the first pre-stage connection TSV3 or the second operating voltage VSS.

When the transistor M1 is in a conductive state, when the second post-stage connection TSV2 is coupled to the post-stage chip, the multiplexer circuit MUX1 is controlled by detecting a first preset voltage upVDD from the post-stage chip through the second post-stage connection TSV2 to select to connect the first post-stage connection TSV1 to the resistor circuit 114, and when the second post-stage connection TSV2 is not coupled to the post-stage chip, the multiplexer circuit MUX1 is controlled by detecting the ground voltage (or a floating voltage) to select to connect the first operating voltage VCCP to the resistor circuit 114. Similarly, when the transistor M2 is in a conductive state, when the second pre-stage connection TSV4 is coupled to the pre-stage chip, the multiplexer circuit MUX2 is controlled by detecting a second preset voltage dnVDD from the preostage chip through the second pre-stage connection TSV4 to select to connect the first pre-stage connection TSV3 to the resistor circuit 114, and when the second pre-stage connection TSV4 is not coupled to the pre-stage chip, the multiplexer circuit MUX2 is controlled by detecting the ground voltage (or a floating voltage) to select to connect the second operating voltage VSS to the resistor circuit 114. In this way, the resistor circuit of each chip may output a reference voltage corresponding to the chip rank thereof.

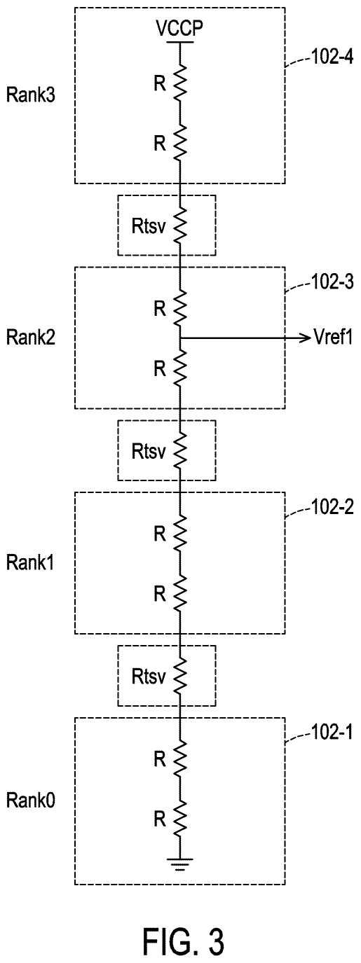

For example, FIG. 3 is an embodiment in which 3 chips are stacked (total 4 chips), wherein the resistor circuit 114 of each chip includes two resistors R coupled in series, and the TSVs between the chips (including the first post-stage connection TSV1 and the first pre-stage connection TSV3) have a resistance Rtsv. Taking the reference voltage Vref1 output by a detection circuit 102-3 corresponding to chip rank 2 as an example, the voltage value of the reference voltage Vref1 may be expressed as the following formula (1).

$$Vref 1 = VCCP \times \frac{Rrank 2}{Rtotal} = VCCP \times \frac{5 R + 2 Rtsv}{8 R + 3 Rtsv} \qquad ( 1 )$$

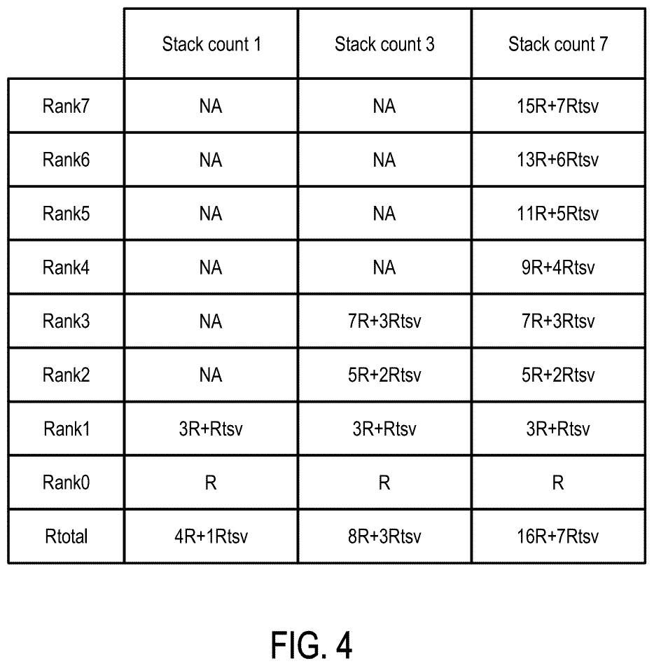

In particular, Rrank2 is the resistance corresponding to chip rank 2, Rtotal is the sum of the resistances of the resistor circuits 114 of the four chips and the resistances of the TSVs between the chips, and with VCCP equal to 2.9 V, R equal to 10 Ohm, and Rtsv equal to 0.8 Ohm, Vref1 equals 1.82 V. By analogy, resistors Rrank0, Rrank1, and Rrank3 corresponding to chip ranks 0, 1, and 3 may be shown in FIG. 4, which are R, 3R+Rtsv, and 7R+3Rtsv respectively. In this way, detection circuits 102-0 to 102-4 of different chip ranks may correspondingly output reference voltages Vref1 having different voltage values, so that the identification circuit 104 of each chip may determine the rank of each chip based on the reference voltage Vref1 provided by the corresponding detection circuit 102. In addition, as shown in FIG. 4, the number of stacked chips is not limited to the embodiment of FIG. 3. In other embodiments, fewer or more chips may be stacked, such as 1 or 7 chips.

Furthermore, the identification circuit 104 may include a voltage dividing circuit 202, a selection circuit 204, and a determination circuit 206, the voltage dividing circuit 202 is coupled to the resistor circuit 114 and the selection circuit 204, and the selection circuit 204 is coupled to the resistor circuit 114 and the determination circuit 206. The voltage dividing circuit 202 may include an n number of voltage dividing resistor circuits. The first voltage dividing resistor circuit divides the reference voltage Vref1 to generate the first dividing voltage, and the n-th voltage dividing resistor circuit divides the n-1-th divided voltage output by the n-1-th voltage dividing resistor circuit to generate the n-th divided voltage, wherein n is an integer greater than 1. For example, in the embodiment of FIG. 2, the voltage dividing circuit 202 includes voltage dividing resistor circuits 210 and 212. The voltage dividing resistor circuit 210 includes resistors RD3 and RD4, and the voltage dividing resistor circuit 212 includes resistors RD5 and RD6. The resistors RD3 and RD4 are coupled in series between the common contact of the resistors RD1 and RD2 and the ground, and the resistors RD5 and RD6 are coupled in series between the common contact of the resistors RD3 and RD4 and the ground, wherein the resistors RD3 and RD4 may have the same resistance value, and the resistors RD5 and RD6 may have the same resistance value, but are not limited thereto. The voltage dividing resistor circuit 210 may divide the reference voltage Vref1 provided by the resistor circuit 114 to generate a first divided voltage Vref2, and the voltage dividing resistor circuit 212 may divide the first divided voltage Vref2 provided by the voltage dividing resistor circuit 210 to generate a second divided voltage Vref3.

The selection circuit 204 may select one of the reference voltage Vref1, the first divided voltage Vref2, and the second divided voltage Vref3 as an output signal VO1 based on the reference voltage Vref1, the first divided voltage Vref2, a first threshold voltage V1, and a second threshold voltage V2. In particular, in the embodiment of FIG. 3, the first threshold voltage V1 and the second threshold voltage V2 may, for example, be set to a voltage value between 0.634 and 0.816 based on the first operating voltage VCCP, the second operating voltage VSS, the resistor R, and the resistor Rtsv. For example, the first threshold voltage V1 and the second threshold voltage V2 are set to 0.8 V, but are not limited thereto. The first threshold voltage V1 and the second threshold voltage V2 may be, for example, voltages provided by a bandgap voltage reference circuit. The determination circuit 206 may determine the rank of the chip according to the output signal VO1 and output an identification signal SC1.

Furthermore, the selection circuit 204 may include comparator circuits CP1 and CP2 and a multiplexer circuit 208, the positive and negative input terminals of the comparator circuit CP1 are respectively coupled to the reference voltage Vref1 and the first threshold voltage V1, the positive and negative input terminals of the comparator circuit CP2 are respectively coupled to the first divided voltage Vref2 and the second threshold voltage V2, and the input terminals of the comparator circuits CP1 and CP2 are coupled to the selection control terminal of the multiplexer circuit 208. The input terminal of the multiplexer circuit 208 receives the reference voltage Vref1, the first divided voltage Vref2, and the second divided voltage Vref3. The output terminal of the multiplexer circuit 208 is coupled to the determination circuit 206.

The multiplexer circuit 208 may select one of the reference voltage Vref1, the first divided voltage Vref2, and the second divided voltage Vref3 as the output signal VO1 based on a comparison voltage VP1 output by the comparator circuit CP1 after comparing the reference voltage Vref1 with the first threshold voltage V1 and a comparison voltage VP2 output by the comparator circuit CP2 after comparing the first divided voltage Vref2 with the second threshold voltage V2. The determination circuit 206 may determine the chip rank according to the output signal VO1, and output the identification signal SC1 accordingly.

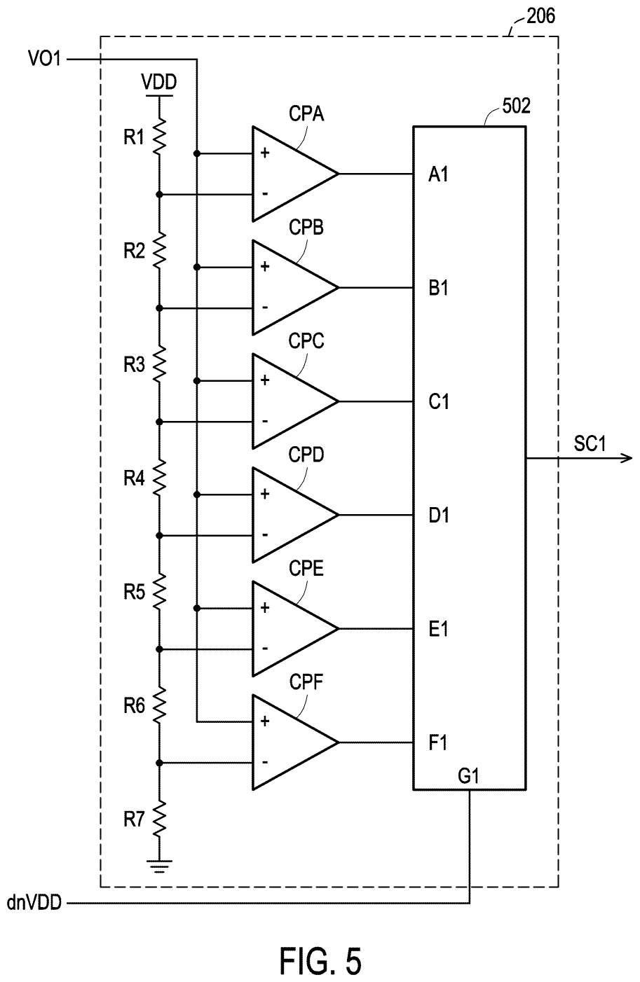

Furthermore, the determination circuit 206 may be implemented in the manner shown in FIG. 5, for example. The determination circuit 206 may include resistors R1 to R7, comparator circuits CPA to CPF, and a logic circuit 502. The positive input terminals of the comparator circuits CPA to CPF receive the output signal VO1 provided by the selection circuit 204, and the output terminals of the comparator circuits CPA to CPF are respectively coupled to input terminals

A to F of the logic circuit 502. The resistors R1 to R7 are coupled in series between a power supply voltage VDD and the ground. The common contact of two adjacent resistors is coupled to the negative input terminals of the corresponding comparator circuits CPA to CPF. In addition, an input terminal G1 of the logic circuit 502 is coupled to the contact of the second pre-stage connection TSV4 to receive the second preset voltage dnVDD. In the case of stacking 7 chips (total 8 chips) or less, the logic circuit 502 can, for example, use a 3-bit signal as the identification signal SC1. Bit values CID<0>, CID<1>, and CID<2> of the identification signal SC1 may be as shown in the following formulas (2) to (4).

$$CID 〈 0 〉 = ( \overline{B} + E \overline{F} + C \overline{D} ) \overline{G} \qquad ( 2 )$$

$$CID 〈 1 〉 = ( \overline{D} + \overline{F} ) \overline{G} \qquad ( 3 )$$

$$CID 〈 2 〉 = ( \overline{C} + D \overline{F} ) \overline{G} \qquad ( 4 )$$

In this way, the chip rank identification circuit 100 of each chip provides the identification signal SC1 indicating the chip rank, thereby effectively achieving the rank identification of the chip.

Based on the above, the first control circuit of an embodiment of the invention couples the resistor circuit to the first operating voltage or the first post-stage connection TSV based on the connection situation with the post-stage chip. The second control circuit couples the resistor circuit to the second operating voltage or the first pre-stage connection TSV based on the connection situation with the pre-stage chip. The identification circuit may determine the rank of the chip based on the reference voltage provided by the resistor circuit. Since in an embodiment of the invention, only two TSVs are occupied between two chips, the area of TSVs may be effectively used and rank identification of the chips may be achieved.

What is claimed is:

1. A chip rank identification circuit, suitable for detecting a rank of a chip, comprising:
a detection circuit having a first contact, a second contact and the detection circuit comprising:
a first switching circuit coupled to the first contact;
a resistor circuit coupled to the first switching circuit;
a first control circuit coupled to the first switching circuit and the second contact and determining whether the chip is coupled to a post-stage chip based on a voltage on the second contact to control the first switching circuit to switch the resistor circuit to be coupled to the first contact or switch the resistor circuit to be coupled to a first operating voltage; and
an identification circuit coupled to the resistor circuit and determining the rank of the chip based on a reference voltage provided by the resistor circuit.

2. The chip rank identification circuit of claim 1, wherein the detection circuit comprises:
a third contact;
a fourth contact;
a second switching circuit; and
a second control circuit coupled to the second switching circuit and the fourth contact and determining whether the chip is coupled to a pre-stage chip based on a voltage on the fourth contact to control the second switching circuit to switch the resistor circuit to be coupled to the third contact or switch the resistor circuit to be coupled to a second operating voltage.

3. The chip rank identification circuit of claim 2, wherein the identification circuit comprises:
a voltage dividing circuit coupled to the resistor circuit and dividing the reference voltage to generate a first divided voltage;
a selection circuit selecting the reference voltage or the first divided voltage as an output signal according to the reference voltage, the first divided voltage, a first threshold voltage, and a second threshold voltage; and
a determination circuit determining the rank of the chip based on the output signal.

4. The chip rank identification circuit of claim 3, wherein the selection circuit comprises:
a first comparator circuit, wherein positive and negative input terminals thereof are coupled to the first threshold voltage and the reference voltage;
a second comparator circuit, wherein positive and negative input terminals thereof are coupled to the second threshold voltage and the first divided voltage; and
a multiplexer circuit coupled to output terminals of the first comparator circuit and the second comparator circuit and outputting the reference voltage or the first divided voltage according to a comparison result of the first comparator circuit and the second comparator circuit, and the determination circuit determines the rank of the chip according to the output signal.

5. The chip rank identification circuit of claim 3, wherein the determination circuit comprises:
a plurality of comparators, wherein positive input terminals thereof receive the output signal;
a plurality of resistors coupled in series between the first threshold voltage and a ground, and nodes between adjacent resistors are coupled to negative input terminals of corresponding comparators; and
a logic circuit coupled to output terminals of the comparators and the fourth contact, and outputting an identification signal indicating the rank of the chip based on output voltages of the comparators and the voltage on the fourth contact.

6. The chip rank identification circuit of claim 2, wherein the resistor circuit comprises:
a first resistor; and
a second resistor coupled in series with the first resistor between the first switching circuit and the second switching circuit, and a common contact of the first resistor and the second resistor generates the reference voltage.

7. The chip rank identification circuit of claim 1, wherein the first switching circuit is a multiplexer circuit, an input terminal thereof is coupled to the first operating voltage and the first contact, an output terminal of the multiplexer circuit is coupled to the resistor circuit, and a control terminal of the multiplexer circuit is coupled to the first control circuit.

8. The chip rank identification circuit of claim 7, wherein the first control circuit comprises a transistor, a first terminal thereof is coupled to the control terminal of the multiplexer circuit and the second contact, a second terminal of the transistor is coupled to a ground, a control terminal of the transistor is controlled by an enabling signal to be turned on, and the transistor generates a selection control signal based on the voltage on the first terminal of the transistor to control the multiplexer circuit to couple the resistor circuit to the first contact or the first operating voltage.

9. The chip rank identification circuit of claim 2, wherein the second switching circuit is a multiplexer circuit, an input terminal thereof is coupled to the second operating voltage and the third contact, an output terminal of the multiplexer circuit is coupled to the resistor circuit, and a control terminal of the multiplexer circuit is coupled to the second control circuit.

10. The chip rank identification circuit of claim 9, wherein the second control circuit comprises a transistor, a first terminal thereof is coupled to the control terminal of the multiplexer circuit and the fourth contact, a second terminal of the transistor is coupled to a ground, a control terminal of the transistor is controlled by an enabling signal to be turned on, and the transistor generates a selection control signal based on the voltage on the first terminal of the transistor to control the multiplexer circuit to couple the resistor circuit to the third contact or the second operating voltage.

11. The chip rank identification circuit of claim 2, wherein the third contact is directly or indirectly connected to a first pre-stage connection TSV.

12. The chip rank identification circuit of claim 11, wherein the chip is coupled to a pre-stage chip by the first pre-stage connection TSV.

13. The chip rank identification circuit of claim 12, wherein the fourth contact is directly or indirectly connected to a second pre-stage connection TSV, and the chip is coupled to the pre-stage chip by the second pre-stage connection TSV.

14. The chip rank identification circuit of claim 2, wherein the first contact is directly or indirectly connected to a first post-stage connection TSV.

15. The chip rank identification circuit of claim 14, wherein the chip is coupled to a poste-stage chip by the first post-stage connection TSV.

16. The chip rank identification circuit of claim 15, wherein the second contact is directly or indirectly connected to a second post-stage connection TSV, and the chip is coupled to the post-stage chip by the second post-stage connection TSV.
